(19) United States
(12) Patent Application Publication
(10) Pub. No.: US 2025/0323603 A1
(43) Pub. Date: Oct. 16, 2025

(54) BIAS CIRCUIT FOR CASCODE FET AMPLIFIER WITH VARIABLE DRAIN BIAS

(71) Applicant: Raytheon Company, Tewksbury, MA (US)

(72) Inventors: John P. Bettencourt, Boxford, MA (US); Edward A. Watters, Carlisle, MA (US); Joseph P. Davis, Andover, MA (US)

(21) Appl. No.: 18/632,014

(22) Filed: Apr. 10, 2024

(51) Int. Cl. H03F 1/22; G05F 3/26; H03F 1/30; H03F 3/193

(52) U.S. Cl. CPC H03F 1/223; G05F 3/262; H03F 1/301; H03F 3/193; H03F 2200/451; H03F 2200/555

(57) ABSTRACT

A circuit includes a bias circuit configured to be coupled to a cascode field effect transistor (FET) amplifier. The bias circuit is configured to receive a variable supply voltage, to generate a reference current independent of the variable supply voltage, and to mirror the reference current as a copy current in the cascode FET amplifier. The bias circuit includes a first follower network, a second follower network, and a third follower network. The first follower network is configured to receive the variable supply voltage and to generate an adjusted voltage less than the variable supply voltage for the bias circuit. The second follower network is coupled to the first follower network and is configured to provide a voltage-level shift based on the adjusted voltage. The third follower network is coupled to the second follower network and is configured to buffer the second follower network against a sink current from and a source current to the cascode FET amplifier.

### GOVERNMENT RIGHTS

This invention was made with government support. The government has certain rights in the invention.

### TECHNICAL FIELD

This disclosure relates generally to bias circuits. More specifically, this disclosure relates to a bias circuit for cascode field effect transistor (FET) amplifiers with variable drain bias.

### BACKGROUND

Radio frequency (RF) transistor amplifiers have a wide range of applications. In some of these applications, it is desirable to vary the RF power provided by these amplifiers. One type of RF amplifier includes Group III-V semiconductor, depletion-mode, field effect transistors (FETs) arranged in a cascode configuration, with a common source and common gate section, that operates with both a positive voltage supply (+V) and a ground potential. The RF FET gate of the RF amplifier has a proper quiescent direct current (DC) bias voltage, in addition to a significantly smaller quiescent DC gate current. The DC bias voltage comes from a DC voltage source. Additionally, this gate current can become a function of an RF signal fed to the gate of the RF FETs. Often, the DC voltage source is provided by a current mirror bias network that is connected between the positive voltage supply +V and a negative voltage supply −V. Some RF amplifiers can be switched between lower power and higher power applications by varying the positive voltage supply +V provided to the RF amplifier. For these RF amplifiers, the components of the current mirror bias network are likewise subjected to a large variation in voltage.

### SUMMARY

This disclosure relates to a bias circuit for cascode or similar stacked field effect transistor (FET) amplifier with variable drain bias.

In a first embodiment, a circuit includes a bias circuit configured to be coupled to a cascode FET amplifier. The bias circuit is configured to receive a variable supply voltage, to generate a reference current independent of the variable supply voltage, and to mirror the reference current as a copy current in the cascode FET amplifier. The bias circuit includes a first follower network, a second follower network, and a third follower network. The first follower network is configured to receive the variable supply voltage and to generate an adjusted voltage less than the variable supply voltage for the bias circuit. The second follower network is coupled to the first follower network and is configured to provide a voltage-level shift based on the adjusted voltage. The third follower network is coupled to the second follower network and is configured to buffer the second follower network against a sink current from and a source current to the cascode FET amplifier.

In a second embodiment, a circuit includes a cascode FET amplifier and a bias circuit. The cascode FET amplifier is configured to operate based on a variable supply voltage. The bias circuit is coupled to the cascode FET amplifier and is configured to generate a reference current and to mirror the reference current as a copy current in the cascode FET amplifier. The bias circuit includes a first follower network, a second follower network, and a third follower network. The first follower network includes a transistor and a voltage divider. A drain electrode of the transistor is coupled to the variable supply voltage. A source electrode of the transistor is configured to provide an adjusted voltage for the bias circuit based on the variable supply voltage. The second follower network is coupled to the first follower network and is configured to provide a voltage-level shift based on the adjusted voltage. The third follower network is coupled to the second follower network and is configured to buffer the second follower network against a sink current from and a source current to the cascode FET amplifier.

In a third embodiment, a circuit includes a cascode FET amplifier and a bias circuit. The cascode FET amplifier is configured to operate based on a variable supply voltage. The bias circuit is coupled to the cascode FET amplifier and is configured to receive a sink current from the cascode FET amplifier, to provide a source current to the cascode FET amplifier, to generate a reference current, and to mirror the reference current as a copy current in the cascode FET amplifier. The bias circuit includes a first follower network, a second follower network, and a third follower network. The first follower network includes a transistor and a voltage divider. A drain electrode of the transistor is coupled to the variable supply voltage. A source electrode of the transistor is configured to provide an adjusted voltage for the bias circuit based on the variable supply voltage. The second follower network is coupled to the first follower network and is configured to provide a voltage-level shift based on the adjusted voltage. The third follower network is coupled to the second follower network and is configured to buffer the second follower network against the sink current and the source current.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 illustrates an example of a radio frequency (RF) amplifier circuit that includes a cascode field effect transistor (FET) amplifier with variable drain bias and a bias circuit according to this disclosure;

FIG. 2 illustrates an example of the RF amplifier circuit of FIG. 1 including a circuit diagram of the cascode FET amplifier according to this disclosure;

FIG. 3 illustrates an example of a circuit diagram of the RF amplifier circuit of FIG. 1 according to this disclosure; and

FIG. 4 illustrates another example of a circuit diagram of the RF amplifier circuit of FIG. 1 according to this disclosure.

### DETAILED DESCRIPTION

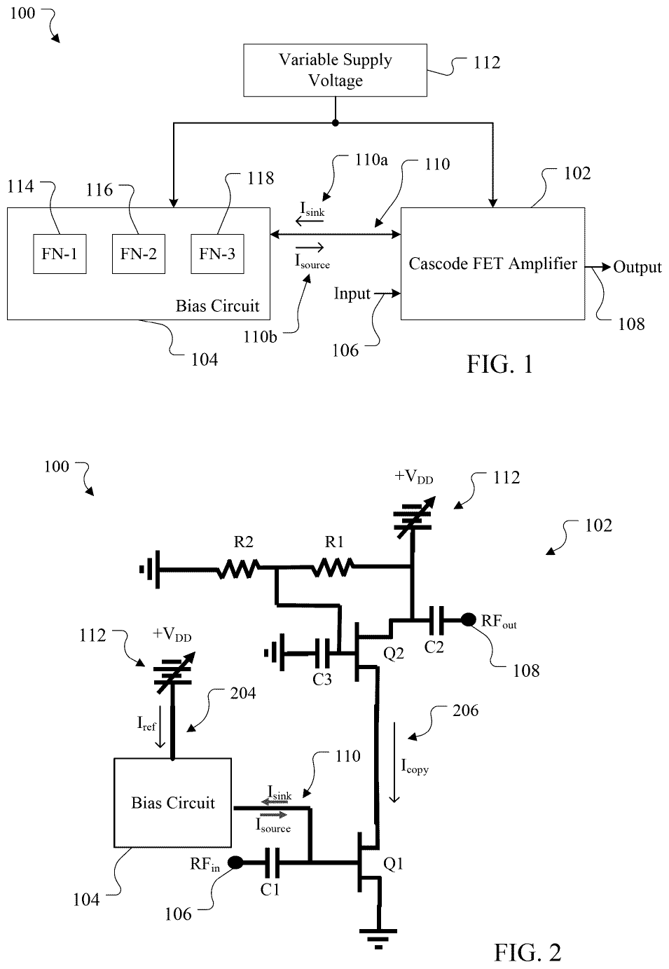

FIGS. 1 through 4, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, radio frequency (RF) transistor amplifiers have a wide range of applications. In some of these applications, it is desirable to vary the power provided to these amplifiers. One type of RF amplifier includes Group III-V semiconductor, depletion-mode (D-mode), field effect transistors (FETs) arranged in a cascode configuration that operates with both a positive voltage supply (+V) and a ground potential. More particularly, the drain of the common gate RF FET is coupled to +V, and the source of the common source FET is coupled to ground where the gate is fed by an RF input signal.

The Common Source RF FET gate of the RF amplifier has a proper quiescent direct current (DC) bias voltage, in addition to a small quiescent DC gate current. This DC bias voltage comes from a DC voltage source, with the gate current typically being a function of the RF input signal fed to the gate of the RF FET. Often, the DC voltage source is provided by a current mirror bias network that is connected between the positive voltage supply +V and a negative voltage supply −V. Thus, if a large variation in the positive voltage supply +V may be implemented for high-power applications of the amplifier, the components of the current mirror bias network are likewise subjected to a large variation in voltage. This disclosure provides a follower network for the current mirror bias network that is configured to decrease the voltage variation seen by the components of the current mirror bias network, thereby reducing stress on those components.

FIG. 1 illustrates an example of an RF amplifier circuit 100 that includes a cascode FET amplifier 102 and a bias circuit 104 according to this disclosure. The embodiment of the RF amplifier circuit 100 shown in FIG. 1 is for illustration only. Other embodiments of the RF amplifier circuit 100 could be used without departing from the scope of this disclosure.

According to embodiments of this disclosure, the RF amplifier circuit 100 can include a D-mode, high-voltage, gallium nitride (GaN), RF amplifier circuit. This type of RF amplifier circuit 100 may be used to implement a high-power application. As described in more detail below in connection with FIGS. 2-4, the cascode FET amplifier 102 includes an RF input 106 coupled to the gate of a first transistor with a common source and a second transistor arranged as a common gate with a drain electrode coupled to an RF output 108. The transistors are configured in a cascode arrangement consisting of a common source input transistor and a common gate transistor. The drain of the common source input transistor is coupled to the source of the common gate transistor. By using this arrangement, the voltage drops across each of the cascode transistors is reduced as compared to the same total voltage drop across a single transistor, thereby allowing the amplifier 102 to deliver higher power without overloading the transistors and potentially causing them to fail.

The common source input transistor of the amplifier 102 is configured to receive an RF input 106, and the common gate transistor of the amplifier 102 is configured to generate an RF output 108. The amplifier 102 is also configured to provide a current 110 to, or receive a current 110 from, the bias circuit 104. For example, when there is no RF signal at the input 106 of the amplifier 102 the amplifier 102 may provide a sink current Iₛᵢₙₖ 110a that is an output to the bias circuit 104. Alternatively, when an RF signal is provided at the input 106 of the amplifier 102, the amplifier 102 provides a source current I_{source} 110b that is an output to the bias circuit 104. Thus, during operation, the amplifier 102 may be configured to generate the output 108 based on an RF signal at the input 106 and the source current 110b from the bias circuit 104.

The amplifier 102 and the bias circuit 104 are each configured to operate based on a shared, variable supply voltage 112. By varying the supply voltage 112, the power for the RF amplifier circuit 100 may be increased or decreased for different applications of the amplifier 102. To provide for higher power applications of the amplifier 102 that use a greater supply voltage 112 without negatively impacting the functionality of the bias circuit 104, the bias circuit 104 is configured to decrease the variation in the voltage provided to its components as compared to the voltage variation provided to the amplifier 102.

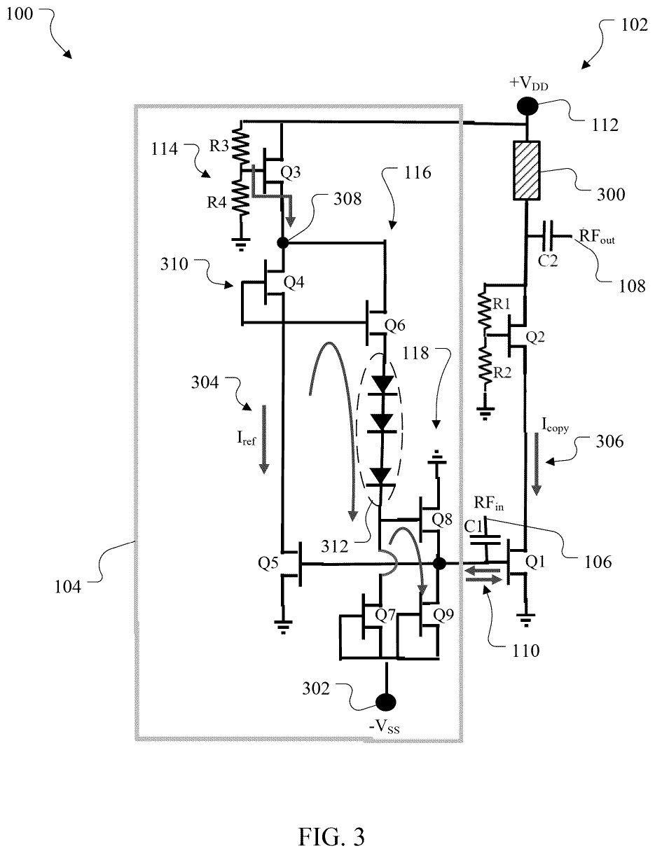

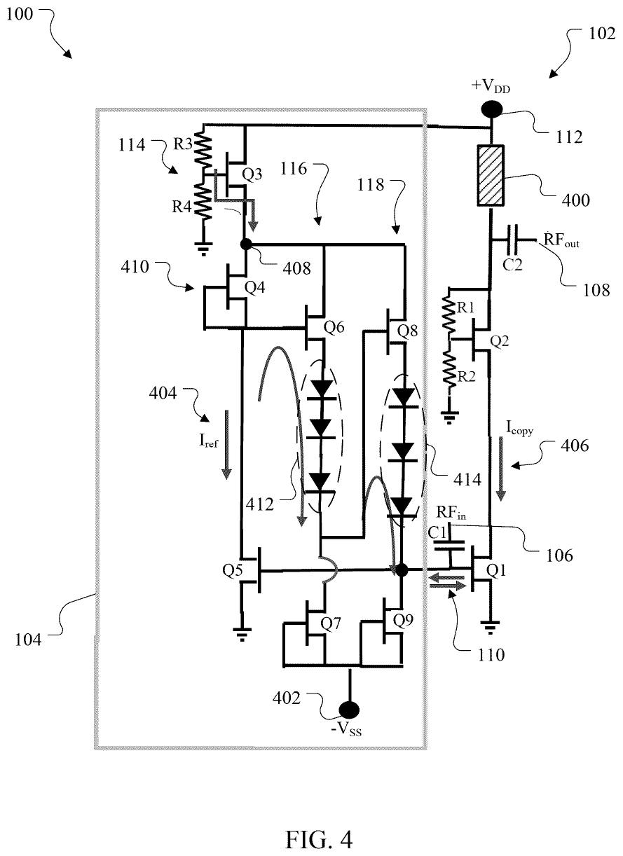

The bias circuit 104 is configured to generate a reference current independent of the supply voltage 112 and to mirror that reference current in the amplifier 102 such that a copy current flowing in the amplifier 102 scales with the reference current. In this way, the bias circuit 104 is configured to set the quiescent conditions of the amplifier 102. As illustrated in FIG. 1, the bias circuit 104 includes three follower networks: a first follower network (FN-1) 114, a second follower network (FN-2) 116, and a third follower network (FN-3) 118. As described in more detail below in connection with FIGS. 3 and 4, the first follower network 114 is configured to generate an adjusted voltage for the bias circuit 104 by decreasing the supply voltage 112. For some embodiments, the variable supply voltage 112 may vary between about 50V and 100V; however, it will be understood that the supply voltage 112 may vary between any suitable voltages based on the application in which the amplifier 102 is being implemented. The first follower network 114 of the bias circuit 104 may be configured to decrease the supply voltage 112 by about half to generate the adjusted voltage. Thus, for a particular example, for the embodiment in which the supply voltage 112 for the amplifier 102 may vary between about 50V and 100V, the first follower network 114 may be configured to provide a voltage that varies between about 25V and 50V for the other components of the bias circuit 104, thereby reducing stress on those components due to voltage variation.

As described in more detail below in connection with FIGS. 3 and 4, the second follower network 116 of the bias circuit 104 is configured to provide a voltage-level shift from a drain electrode to a gate electrode for a current mirror transistor of the bias circuit 104. The current mirror transistor is configured to mirror the reference current as the copy current in the amplifier 102. The third follower network 118 of the bias circuit 104 is configured to buffer the second follower network 116 against sink current 111a and source current 110b, which allows for a wider range of operation when source current 110a or sink current 110b is present.

Although FIG. 1 illustrates one example of an RF amplifier circuit 100, various changes may be made to FIG. 1. For instance, the RF amplifier circuit 100 may include additional components not shown in FIG. 1. In addition, the first follower network 114 may decrease the voltage variation of the supply voltage 112 by any suitable percentage. Also, the first follower network 114 may be implemented with a series of diodes, resistors and/or other DC level shifting circuits.

FIG. 2 illustrates an example of the RF amplifier circuit 100 of FIG. 1 including a circuit diagram of the cascode FET amplifier 102 according to this disclosure. The embodiment of the cascode FET amplifier 102 shown in FIG. 2 is for illustration only. Other embodiments of the cascode FET amplifier 102 could be used without departing from the scope of this disclosure.

According to embodiments of this disclosure, the amplifier 102 includes an RF input 106 coupled to the gate of a common source input transistor Q1 and a common gate transistor Q2 arranged as a common gate with a drain electrode coupled to an RF output 108. The transistors Q1 and Q2 are configured in a cascode arrangement consisting of a common source input transistor Q1 and a common gate transistor Q2. The drain of the common source input transistor Q1 is coupled to the source of the common gate transistor Q2. Thus, the common source input transistor Q1 and the common gate transistor Q2 are configured in a stacked/cascode arrangement coupled in series from the variable drain supply voltage +V_{DD}112 to ground. Each of these transistors Q1 and Q2 includes an n-channel, D-mode FET. The common source input transistor Q1 has a grounded source electrode and a drain electrode coupled to a source electrode of the common gate transistor Q2. The common gate transistor Q2 has a drain electrode coupled to the variable supply voltage 112. For some embodiments, the variable supply voltage 112 may vary between about 50V and 100V; however, it will be understood that the supply voltage 112 may vary between any suitable voltages based on the application in which the amplifier 102 is being implemented.

For the illustrated embodiment, the amplifier 102 is configured to receive an RF input signal 106, through a capacitor C1, at a gate electrode of the common source input transistor Q1. In addition, the amplifier 102 is configured to generate an RF output signal 108 on the drain electrode of the common gate transistor through capacitor C2. The supply voltage 112 is provided through a voltage divider including resistors R1 and R2 to a gate electrode of the common gate transistor Q2. In addition, a capacitor C3 couples the gate electrode of the common gate transistor Q2 to ground.

It is noted that since the transistors Q1 and Q2 are D-mode transistors whose gate electrodes would typically be DC-biased at a potential more negative than ground potential, the gate electrode of the common source input transistor Q1 is fed from the bias circuit 104. As described in more detail below in connection with FIGS. 3 and 4, the second follower network 116 of the bias circuit 104 is coupled between the adjusted voltage provided by the first follower network 114 and a negative voltage supply, and the third follower network 118 is coupled either between ground and the negative voltage supply or between the adjusted voltage and the negative voltage supply. Thus, a potential more negative than ground potential is provided through the bias circuit 104.

The bias circuit 104 is configured to receive the supply voltage 112, to generate a reference current 204 independent of the supply voltage 112, and to mirror that reference current 204 as a copy current 206 in the amplifier 102. As described above in connection with FIG. 1, the bias circuit 104 is also configured to receive a current 110 from, or provide a current 110 to, the gate electrode of the common source input transistor Q1 of the amplifier 102. Thus, when no RF input 106 is present, a sink current 110a may flow from the gate electrode of the common source input transistor Q1 to the bias circuit 104, and when an RF input 106 is present, a source current 110b may flow from the bias circuit 104 to the gate electrode of the common source input transistor Q1.

Although FIG. 2 illustrates one example of an RF amplifier circuit 100, various changes may be made to FIG. 2. For instance, the cascode FET amplifier 102 may include other or additional components. In addition, the first follower network 114 may decrease the voltage variation of the supply voltage 112 by any suitable percentage.

FIG. 3 illustrates an example of a circuit diagram of the RF amplifier circuit 100 of FIG. 1 according to this disclosure. The embodiment of the RF amplifier circuit 100 shown in FIG. 3 is for illustration only. Other embodiments of the RF amplifier circuit 100 could be used without departing from the scope of this disclosure.

According to embodiments of this disclosure, the amplifier 102 includes an RF input 106 coupled to the gate of a common source input transistor Q1 and a common gate transistor Q2 arranged as a common gate with a drain electrode coupled to an RF output 108. The transistors Q1 and Q2 are configured in a cascode arrangement consisting of a common source input transistor Q1 and a common gate transistor Q2. The drain of the common source input transistor Q1 is coupled to the source of the common gate transistor Q2. Thus, the common source input transistor Q1 and the common gate transistor Q2 are configured in a stacked/cascode arrangement coupled in series from the variable drain supply voltage +V_{DD}112 to ground. Each of these transistors Q1 and Q2 includes an n-channel, D-mode FET. The common source input transistor Q1 has a grounded source electrode and a drain electrode coupled to a source electrode of the common gate transistor Q2. The common gate transistor Q2 has a drain electrode coupled to the variable supply voltage 112 via an RF load impedance 300. For some embodiments, the variable supply voltage 112 may vary between about 50V and 100V; however, it will be understood that the supply voltage 112 may vary between any suitable voltages based on the application in which the amplifier 102 is being implemented.

For the illustrated embodiment, the amplifier 102 is configured to receive an RF input signal 106, through a capacitor C1, at a gate electrode of the common source input transistor Q1. In addition, the amplifier 102 is configured to generate an RF output signal 108 at the drain electrode of the common gate transistor Q2 through a capacitor C2. The voltage at the drain electrode of the common gate transistor Q2 is provided through a voltage divider including resistors R1 and R2 to a gate electrode of the common gate transistor Q2.

It is noted that since the transistors Q1 and Q2 are D-mode transistors whose gate electrodes would typically be DC-biased at a potential more negative than ground potential, the gate electrode of the common source input transistor Q1 is fed from the bias circuit 104, which is coupled to a negative supply voltage −V_{SS} 302. For some embodiments, the negative supply voltage 302 may be about −5V; however, it will be understood that the negative supply voltage 302 may be any suitable voltage more negative than ground potential based on the application in which the amplifier 102 is being implemented. The negative supply voltage 302 is configured to enable proper operation of D-mode devices, such as the transistors Q1 and Q2.

The bias circuit 104 is configured to receive the variable supply voltage 112 and to generate a reference current 304 based on that supply voltage 112. The bias circuit 104 is also configured to mirror the reference current 304 as a copy current 306 in the amplifier 102. As described above in connection with FIG. 1, the bias circuit 104 is also configured to receive a current 110 from, or provide a current 110 to, the gate electrode of the common source input transistor Q1 of the amplifier 102. Thus, when no RF input 106 is present, a sink current 111a may flow from the gate electrode of the common source input transistor Q1 to the bias circuit 104, and when an RF input 106 is present, a source current 110b may flow from the bias circuit 104 to the gate electrode of the common source input transistor Q1.

According to embodiments of the disclosure, the first follower network 114 includes a transistor Q3 and a voltage divider, which includes resistors R3 and R4. The transistor Q3 has a drain electrode coupled to the variable supply voltage 112. The resistor R3 is coupled between the supply voltage 112 and a gate electrode of the transistor Q3. The resistor R4 is coupled between the gate electrode of the transistor Q3 and ground. The first follower network 114 is configured to provide an adjusted voltage 308 at a source electrode of the transistor Q3 that is less than the voltage provided by the supply voltage 112. For example, for a particular embodiment in which the resistors R3 and R4 have the same resistance as each other, the first follower network 114 is configured to provide an adjusted voltage 308 at the source electrode of the transistor Q3 that is about half the voltage provided by the supply voltage 112.

The bias circuit 104 also includes a current source 310, here a current source transistor Q4, for producing the reference current 304 and a current mirror transistor Q5 coupled to the current source 310. The current source 310 is coupled to the first follower network 114. For the illustrated embodiment, a drain electrode of the current source transistor Q4 is coupled to the source electrode of the transistor Q3. The current source transistor Q4 may be configured to supply the reference current 304 to the current mirror transistor Q5 for the bias circuit 104. The current mirror transistor Q5 has a grounded source electrode and a drain electrode coupled to the source electrode of the current source transistor Q4. A gate electrode of the current mirror transistor Q5 is coupled to the gate electrode of the common source input transistor Q1. The current mirror transistor Q5 is configured to mirror the reference current 304 in the amplifier 102 as the copy current 306.

The second follower network 116 is coupled between the source electrode of the transistor Q3, which provides the adjusted voltage 308 based on the supply voltage 112, and the negative supply voltage −V_{SS} 302. The second follower network 116 includes a transistor Q6, a plurality of serially-coupled diodes 312, and a FET load Q7. For the illustrated embodiment, the diodes 312 include three serially-coupled diodes. A drain electrode of the transistor Q6 is coupled to the source electrode of the transistor Q3 and the drain electrode of the current source transistor Q4. A gate electrode of the transistor Q6 is coupled to a gate electrode of the current source transistor Q4 and source electrode of Q4. A source electrode of the transistor Q6 is coupled to a first end of the diodes 312. A second end of the diodes 312 is coupled to a drain electrode of the FET load Q7. A gate electrode and a source electrode for the FET load Q7 are each coupled to the negative supply voltage 302. The second follower network 116 is configured to provide a voltage-level shift from the drain electrode to the gate electrode of the current mirror transistor Q5. In addition, the second follower network 116 is configured to provide an output to the third follower network 118 at the second end of the diodes 312, as described below.

The third follower network 118 is coupled between ground reference and the negative supply voltage −V_{SS} 302. The third follower network 118 includes a voltage follower FET Q8 and a FET load Q9. A drain electrode for the voltage follower FET Q8 is coupled to ground. A gate electrode for the voltage follower FET Q8 is coupled to the second follower network 116 at both the drain electrode of the FET load Q7 and the second end of the diodes 312. A source electrode for the voltage follower FET Q8, which provides an output of the third follower network 118, is coupled to the gate electrode for the common source input transistor Q1 of the amplifier 102 and to the gate electrode for the current mirror transistor Q5 of the bias circuit 104. The source electrode for the voltage follower FET Q8 is also coupled to a drain electrode for the FET load Q9. A gate electrode and a source electrode for the FET load Q9 are each coupled to the negative supply voltage 302.

The third follower network 118 is configured to buffer the second follower network 116 against sink current 110a from, and source current 110b to, the gate electrode of the common source input transistor Q1, thereby allowing for a wider range of operation when either sink current 110a or source current 110b is present. In addition, the third follower network 118 is configured to provide a feedback control voltage at the gate electrode of the current mirror transistor Q5.

In this way, the follower networks 114, 116 and 118 are together configured to enable voltage-level shifted feedback with power supply/drain bias variation, common source stage sink and large signal source current operation. Also, the follower networks 114, 116 and 118 are together configured to improve the operating range of the amplifier 102 with variation in the supply voltage 112. In addition, because the bias circuit 104 separates the main current path through the amplifier 102 from the control loop through the series of follower networks 114, 116 and 118, the control loop is allowed to function independently of the current load seen by the bias circuit 104. The bias circuit 104 is also configured to set proper quiescent conditions in the common source input transistor Q1 of the amplifier 102, allow for a large copy current 306 through the amplifier 102, accommodate sink current 110a, and provide for operation of the amplifier 102 over a wide range of drain supply voltages from the variable supply voltage 112.

Although FIG. 3 illustrates one example of an RF amplifier circuit 100, various changes may be made to FIG. 3. For instance, the cascode FET amplifier 102 and/or the bias circuit 104 may each include other or additional components. In addition, the first follower network 114 may decrease the voltage variation of the supply voltage 112 by any suitable percentage. Also, similar to the embodiment illustrated in FIG. 2, the amplifier 102 may include a capacitor coupled between the gate electrode of the common gate transistor Q2 and ground. In addition, instead of a current source transistor Q4, the current source 310 may be a saturated resistor, a semiconductor resistor scaled to behave as a current source, or other suitable component. The serially-coupled diodes 312 may also include any suitable number of diodes.

FIG. 4 illustrates an example of a circuit diagram of the RF amplifier circuit 100 of FIG. 1 according to this disclosure. The embodiment of the RF amplifier circuit 100 shown in FIG. 4 is for illustration only. Other embodiments of the RF amplifier circuit 100 could be used without departing from the scope of this disclosure.

According to embodiments of this disclosure, the amplifier 102 includes an RF input 106 coupled to the gate of a common source input transistor Q1 and a common gate transistor Q2 arranged as a common gate with a drain electrode coupled to an RF output 108. The transistors Q1 and Q2 are configured in a cascode arrangement consisting of a common source input transistor Q1 and a common gate transistor Q2. The drain of the common source input transistor Q1 is coupled to the source of the common gate transistor Q2. Thus, the common source input transistor Q1 and the common gate transistor Q2 are configured in a stacked/cascode arrangement coupled in series from the variable drain supply voltage +V_{DD}112 to ground. Each of these transistors Q1 and Q2 includes an n-channel, D-mode FET. The common source input transistor Q1 has a grounded source electrode and a drain electrode coupled to a source electrode of the common gate transistor Q2. The common gate transistor Q2 has a drain electrode coupled to the variable supply voltage 112 via an RF load impedance 400. For some embodiments, the variable supply voltage 112 may vary between about 50V and 100V; however, it will be understood that the supply voltage 112 may vary between any suitable voltages based on the application in which the amplifier 102 is being implemented.

For the illustrated embodiment, the amplifier 102 is configured to receive an RF input signal 106, through a capacitor C1, at a gate electrode of the common source input transistor Q1. In addition, the amplifier 102 is configured to generate an RF output signal 108 at the drain electrode of the common gate transistor Q2 through a capacitor C2. The voltage at the drain electrode of the common gate transistor Q2 is provided through a voltage divider including resistors R1 and R2 to a gate electrode of the common gate transistor Q2.

It is noted that since the transistors Q1 and Q2 are D-mode transistors whose gate electrodes would typically be DC-biased at a potential more negative than ground potential, the gate electrode of the common source input transistor Q1 is fed from the bias circuit 104, which is coupled to a negative supply voltage −V_{SS} 402. For some embodiments, the negative supply voltage 402 may be about −5V; however, it will be understood that the negative supply voltage 402 may be any suitable voltage more negative than ground potential based on the application in which the amplifier 102 is being implemented. The negative supply voltage 402 is configured to enable proper operation of D-mode devices, such as the transistors Q1 and Q2.

The bias circuit 104 is configured to receive the variable supply voltage 112 and to generate a reference current 404 independent of supply voltage 112. The bias circuit 104 is also configured to mirror the reference current 404 as a copy current 406 in the amplifier 102. As described above in connection with FIG. 1, the bias circuit 104 is also configured to receive a current 110 from, or provide a current 110 to, the gate electrode of the common source input transistor Q1 of the amplifier 102. Thus, when no RF input 106 is present, a sink current 110a may flow from the gate electrode of the common source input transistor Q1 to the bias circuit 104, and when an RF input 106 is present, a source current 110b may flow from the bias circuit 104 to the gate electrode of the common source input transistor Q1.

According to embodiments of the disclosure, the first follower network 114 includes a transistor Q3 and a voltage divider, which includes resistors R3 and R4. The transistor Q3 has a drain electrode coupled to the variable supply voltage 112. The resistor R3 is coupled between the supply voltage 112 and a gate electrode of the transistor Q3. The resistor R4 is coupled between the gate electrode of the transistor Q3 and ground. The first follower network 114 is configured to provide an adjusted voltage 408 at a source electrode of the transistor Q3 that is less than the voltage provided by the supply voltage 112. For example, for a particular embodiment in which the resistors R3 and R4 have the same resistance as each other, the first follower network 114 is configured to provide an adjusted voltage 408 at the source electrode of the transistor Q3 that is about half the voltage provided by the supply voltage 112.

The bias circuit 104 also includes a current source 410, here a current source transistor Q4, for producing the reference current 404 and a current mirror transistor Q5 coupled to the current source 410. The current source 410 is coupled to the first follower network 114. For the illustrated embodiment, a drain electrode of the current source transistor Q4 is coupled to the source electrode of the transistor Q3. The current source transistor Q4 may be configured to supply the reference current 404 to the current mirror transistor Q5 for the bias circuit 104. The current mirror transistor Q5 has a grounded source electrode and a drain electrode coupled to the source electrode of the current source transistor Q4. A gate electrode of the current mirror transistor Q5 is coupled to the gate electrode of the common source input transistor Q1. The current mirror transistor Q5 is configured to mirror the reference current 404 in the amplifier 102 as the copy current 406.

The second follower network 116 is coupled between the source electrode of the transistor Q3, which provides the adjusted voltage 408 based on the supply voltage 112, and the negative supply voltage −V_{SS} 402. The second follower network 116 includes a transistor Q6, a plurality of serially-coupled diodes 412, and a FET load Q7. For the illustrated embodiment, the diodes 412 include three serially-coupled diodes. A drain electrode of the transistor Q6 is coupled to the source electrode of the transistor Q3 and the drain electrode of the current source transistor Q4. A gate electrode of the transistor Q6 is coupled to a gate electrode of the current source transistor Q4 and source electrode of Q4. A source electrode of the transistor Q6 is coupled to a first end of the diodes 412. A second end of the diodes 412 is coupled to a drain electrode of the FET load Q7. A gate electrode and a source electrode for the FET load Q7 are each coupled to the negative supply voltage 402. The second follower network 116 is configured to provide a voltage-level shift from the drain electrode to the gate electrode of the current mirror transistor Q5. In addition, the second follower network 116 is configured to provide an output to the third follower network 118 at the second end of the diodes 412, as described below.

The third follower network 118 is coupled between the source electrode of the transistor Q3, which provides the adjusted voltage 408 based on the supply voltage 112, and the negative supply voltage −V_{SS} 402. The third follower network 118 includes a voltage follower FET Q8, a plurality of serially-coupled diodes 414, and a FET load Q9. For the illustrated embodiment, the diodes 414 include three serially-coupled diodes. A drain electrode for the voltage follower FET Q8 is coupled to the source electrode of the transistor Q3. A gate electrode for the voltage follower FET Q8 is coupled to the second follower network 116 at both the drain electrode of the FET load Q7 and the second end of the diodes 412. A source electrode for the voltage follower FET Q8 is coupled to a first end of the diodes 414. A second end of the diodes 414, which provides an output of the third follower network 118, is coupled to the gate electrode for the common source input transistor Q1 of the amplifier 102 and to the gate electrode for the current mirror transistor Q5 of the bias circuit 104. The second end of the diodes 414 is also coupled to a drain electrode for the FET load Q9. A gate electrode and a source electrode for the FET load Q9 are each coupled to the negative supply voltage 402.

The third follower network 118 is configured to buffer the second follower network 116 against sink current 110a from, and source current 110b to, the gate electrode of the common source input transistor Q1, thereby allowing for a wider range of operation when either sink current 110a or source current 110b is present. In addition, the third follower network 118 is configured to provide a feedback control voltage at the gate electrode of the current mirror transistor Q5.

In this way, the follower networks 114, 116 and 118 are together configured to enable voltage-level shifted feedback with power supply/drain bias variation, common source stage sink and large signal source current operation. Also, the follower networks 114, 116 and 118 are together configured to improve the operating range of the amplifier 102 with variation in the supply voltage 112. In addition, because the bias circuit 104 separates the main current path through the amplifier 102 from the control loop through the series of follower networks 114, 116 and 118, the control loop is allowed to function independently of the current load seen by the bias circuit 104. The bias circuit 104 is also configured to set proper quiescent conditions in the common source input transistor Q1 of the amplifier 102, allow for a large copy current 406 through the amplifier 102, accommodate sink current 110a, and provide for operation of the amplifier 102 over a wide range of drain supply voltages from the variable supply voltage 112.

Although FIG. 4 illustrates one example of an RF amplifier circuit 100, various changes may be made to FIG. 4. For instance, the cascode FET amplifier 102 and/or the bias circuit 104 may each include other or additional components. In addition, the first follower network 114 may decrease the voltage variation of the supply voltage 112 by any suitable percentage. Also, similar to the embodiment illustrated in FIG. 2, the amplifier 102 may include a capacitor coupled between the gate electrode of the common gate transistor Q2 and ground. In addition, instead of a current source transistor Q4, the current source 410 may be a saturated resistor, a semiconductor resistor scaled to behave as a current source, or other suitable component. The set of serially-coupled diodes 412 and also the set of serially-coupled diodes 414 may each include any suitable number of diodes.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A circuit comprising:
a bias circuit configured to be coupled to a cascode field effect transistor (FET) amplifier, the bias circuit configured to receive a variable supply voltage, to generate a reference current independent of the variable supply voltage, and to mirror the reference current as a copy current in the cascode FET amplifier, wherein the bias circuit comprises:
a first follower network configured to receive the variable supply voltage and to generate an adjusted voltage less than the variable supply voltage for the bias circuit;
a second follower network coupled to the first follower network, the second follower network configured to provide a voltage-level shift based on the adjusted voltage; and
a third follower network coupled to the second follower network, the third follower network configured to buffer the second follower network against a sink current from and a source current to the cascode FET amplifier.

2. The circuit of claim 1, wherein:
the first follower network comprises a transistor and a voltage divider; and
the transistor comprises a drain electrode coupled to the variable supply voltage and a source electrode configured to provide the adjusted voltage.

3. The circuit of claim 2, wherein:
the second follower network is coupled between the source electrode of the transistor and a negative supply voltage; and
the third follower network is coupled between a ground potential and the negative supply voltage.

4. The circuit of claim 2, wherein:
the second follower network is coupled between the source electrode of the transistor and a negative supply voltage; and
the third follower network is coupled between the source electrode of the transistor and the negative supply voltage.

5. The circuit of claim 1, further comprising the cascode FET amplifier, wherein:
the cascode FET amplifier is configured to receive an input signal at a common source input transistor and to generate an output signal based on the input signal at a common gate transistor; and
the bias circuit further comprises:
a current source configured to produce the reference current based on the adjusted voltage; and
a current mirror transistor comprising a drain electrode coupled to the current source, a gate electrode coupled to a gate electrode of the common source input transistor, and a source electrode coupled to a ground potential.

6. The circuit of claim 5, wherein:
the current source comprises a current source transistor;
the first follower network comprises a first transistor and a voltage divider;
the second follower network comprises a second transistor, a first set of diodes, and a first FET load;
the first transistor comprises a drain electrode coupled to the variable supply voltage, a gate electrode coupled to the voltage divider, and a source electrode configured to provide the adjusted voltage;
a drain electrode of the second transistor is coupled to the source electrode of the first transistor and a drain electrode of the current source transistor, a gate electrode of the second transistor is coupled to a gate electrode and a source electrode of the current source transistor, and a source electrode of the second transistor is coupled to a first end of the first set of diodes; and
a second end of the first set of diodes is coupled to a drain electrode of the first FET load, and a gate electrode and a source electrode of the first FET load are each coupled to a negative supply voltage.

7. The circuit of claim 6, wherein:
the third follower network comprises a voltage follower FET and a second FET load;
a drain electrode of the voltage follower FET is coupled to the ground potential, a gate electrode of the voltage follower FET is coupled to the drain electrode of the first FET load and the second end of the first set of diodes, and a source electrode of the voltage follower FET is coupled to the gate electrode of the common source input transistor, the gate electrode of the current mirror transistor, and a drain electrode of the second FET load; and
a gate electrode and a source electrode of the second FET load are each coupled to the negative supply voltage.

8. The circuit of claim 6, wherein:
the third follower network comprises a voltage follower FET, a second set of diodes, and a second FET load;
a drain electrode of the voltage follower FET is coupled to the source electrode of the first transistor, a gate electrode of the voltage follower FET is coupled to the drain electrode of the first FET load and the second end of the first set of diodes, and a source electrode of the voltage follower FET is coupled to a first end of the second set of diodes;
a second end of the second set of diodes is coupled to the gate electrode of the common source input transistor, the gate electrode of the current mirror transistor, and a drain electrode of the second FET load; and
a gate electrode and a source electrode of the second FET load are each coupled to the negative supply voltage.

9. The circuit of claim 6, wherein the negative supply voltage is about −5V.

10. The circuit of claim 5, wherein the third follower network is configured to provide a feedback control voltage at a gate electrode of the current mirror transistor.

11. The circuit of claim 5, wherein each of the common source input transistor and the common gate transistor comprises a depletion-mode FET.

12. The circuit of claim 5, wherein the current source comprises a saturated resistor.

13. The circuit of claim 1, wherein the first follower network is further configured to generate the adjusted voltage by decreasing the variable supply voltage by about half.

14. The circuit of claim 1, wherein:
the variable supply voltage is configured to provide a supply voltage between about 50V and 100V; and
the first follower network is configured to generate the adjusted voltage between about 25V and 50V.

15. A circuit comprising:
a cascode field effect transistor (FET) amplifier configured to operate based on a variable supply voltage; and
a bias circuit coupled to the cascode FET amplifier, the bias circuit configured to generate a reference current and to mirror the reference current as a copy current in the cascode FET amplifier, wherein the bias circuit comprises:
a first follower network comprising a transistor and a voltage divider, wherein a drain electrode of the transistor is coupled to the variable supply voltage, and a source electrode of the transistor is configured to provide an adjusted voltage for the bias circuit based on the variable supply voltage;
a second follower network coupled to the first follower network, the second follower network configured to provide a voltage-level shift based on the adjusted voltage; and
a third follower network coupled to the second follower network, the third follower network configured to buffer the second follower network against a sink current from and a source current to the cascode FET amplifier.

16. The circuit of claim 15, wherein the adjusted voltage is about half of the variable supply voltage.

17. The circuit of claim 15, wherein:
the variable supply voltage is between about 50V and 100V;
the adjusted voltage is between about 25V and 50V; and
each of the second follower network and the third follower network is coupled to a negative supply voltage of about −5V.

18. A circuit comprising:
a cascode field effect transistor (FET) amplifier configured to operate based on a variable supply voltage; and
a bias circuit coupled to the cascode FET amplifier, the bias circuit configured to receive a sink current from the cascode FET amplifier, to provide a source current to the cascode FET amplifier, to generate a reference current, and to mirror the reference current as a copy current in the cascode FET amplifier, wherein the bias circuit comprises:
a first follower network comprising a transistor and a voltage divider, wherein a drain electrode of the transistor is coupled to the variable supply voltage, and a source electrode of the transistor is configured to provide an adjusted voltage for the bias circuit based on the variable supply voltage;
a second follower network coupled to the first follower network, the second follower network configured to provide a voltage-level shift based on the adjusted voltage; and
a third follower network coupled to the second follower network, the third follower network configured to buffer the second follower network against the sink current and the source current.

19. The circuit of claim 18, wherein the adjusted voltage is about half of the variable supply voltage.

20. The circuit of claim 18, wherein:
the variable supply voltage is between about 50V and 100V;
the adjusted voltage is between about 25V and 50V; and
each of the second follower network and the third follower network is coupled to a negative supply voltage of about −5V.
